(19) United States
(12) Patent Application Publication
(10) Pub. No.: US 2026/0190887 A1
(43) Pub. Date: Jul. 2, 2026

(54) Etching Method and Etching Device

(71) Applicant: Tokyo Electron Limited, Tokyo (JP)

(72) Inventors: Nobuhiro TAKAHASHI, Yamanashi (JP); Tomoaki FUKUDA, Hillsboro, OR (US)

(21) Appl. No.: 19/547,352

(22) Filed: Feb. 23, 2026

Related U.S. Application Data
(63) Continuation of application No. PCT/JP2024/030058, filed on Aug. 23, 2024.

(30) Foreign Application Priority Data
Sep. 6, 2023 (JP) 2023-144698

(51) Int. Cl. H10P 50/28; H01J 37/32

(52) U.S. Cl. CPC H10P 50/283; H01J 37/3244; H01J 2237/334

(57) ABSTRACT

There is an etching method for etching a carbon-containing silicon oxide film formed on a substrate by exposing the carbon-containing silicon oxide film to plasma generated from an etching gas containing a fluorine-containing gas, an oxygen-containing gas, and a hydrogen gas.

### CROSS-REFERENCE TO RELATED APPLICATIONS

This application is a bypass continuation application of International Application No. PCT/JP2024/030058 having an international filing date of August 23, 2024 and designating the United States, the International Application being based upon and claiming the benefit of priority from Japanese Patent Application No. 2023-144698 filed on September 6, 2023, the entire contents of which are incorporated herein by reference.

### TECHNICAL FIELD

The present disclosure relates to an etching method and an etching apparatus.

### BACKGROUND

In manufacturing a semiconductor device, a carbon-containing silicon oxide film formed on a surface of a semiconductor wafer (hereinafter, referred to as "wafer"), which serves as a substrate, may be etched. Japanese Laid-open Patent Publication No. 2004-512673 discloses etching a carbon-containing silicon oxide film having less than about 30 atomic % of carbon and less than about 50 atomic % of hydrogen by using plasma of a gas containing NH₃ and CₓF_{y}.

### SUMMARY

The present disclosure provides a technique capable of effectively etching a carbon-containing silicon oxide film.

The etching method of the present disclosure etches a carbon-containing silicon oxide film formed on a substrate by exposing the carbon-containing silicon oxide film to plasma generated from an etching gas containing a fluorine-containing gas, an oxygen-containing gas, and a hydrogen gas.

### BRIEF DESCRIPTION OF THE DRAWINGS

FIG. 1 is a longitudinal cross-sectional side view of a wafer to be subjected to an etching process according to one embodiment of the present disclosure.

FIG. 2 is a longitudinal cross-sectional side view of the wafer during etching.

FIG. 3 is a longitudinal cross-sectional side view of the wafer after etching.

FIG. 4 is a longitudinal cross-sectional side view of an etching apparatus that performs an etching process.

FIG. 5 is a longitudinal cross-sectional side view of a heat shield plate in the etching apparatus.

FIG. 6 is a longitudinal cross-sectional side view of another wafer before etching.

FIG. 7 is a longitudinal cross-sectional side view of another wafer after etching.

FIG. 8 is a graph showing the results of an evaluation test.

### DETAILED DESCRIPTION

One embodiment of an etching method of the present disclosure will be described. A plasma etching method described in the present embodiment is used as one step in a manufacturing process of a complementary field-effect transistor (CFET). The CFET has a structure in which an NMOS transistor and a PMOS transistor are stacked on a substrate in the thickness direction of the substrate. More specifically, gates constituting the transistors overlap each other in the thickness direction of the substrate.

Semiconductor films containing Si (silicon) or SiGe (silicon germanium), which are referred to as nanowires or nanosheets, extend through the gates in a direction perpendicular to the thickness direction of the substrate, and each semiconductor film is formed in multiple stages in the thickness direction of the substrate. Since each semiconductor film is surrounded by the gate by penetrating through the gate in this manner, the CFET has a so-called gate all around (GAA) structure. Further, it should be noted that processing during the manufacturing of the CFET is described as an example of the application of the present technology, and application of the present technology is not limited to manufacturing a CFET.

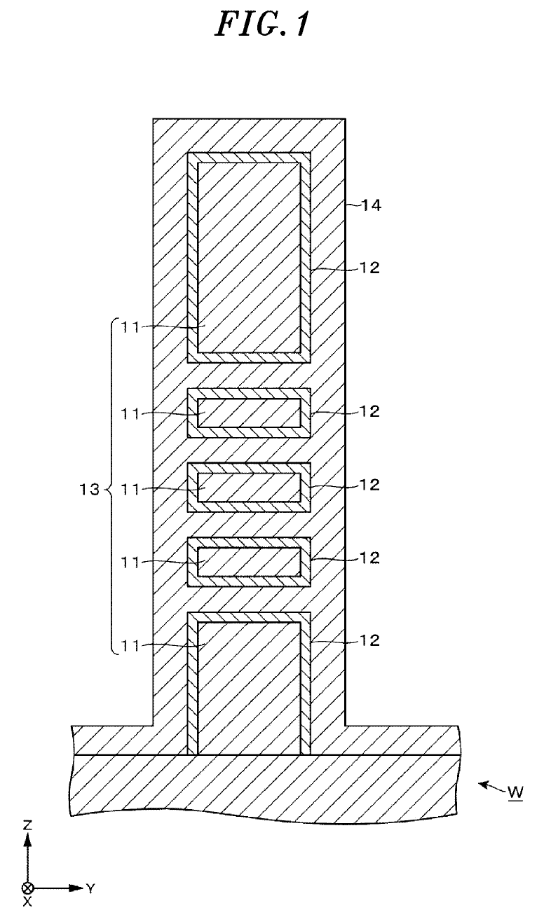

Referring to FIG. 1, a wafer W, which is a substrate to be etched, will be described. FIG. 1 is a longitudinal cross-sectional side view of the surface of the wafer W. In FIG. 1, two directions perpendicular to each other in the surface direction of the wafer W are designated as the X and Y directions, and the thickness direction of the wafer W, which is perpendicular to both the X and Y directions, is designated as the Z direction. FIG. 1 shows the wafer W viewed in the X direction. In the following description of the surface film structure of the wafer W, it is assumed that the wafer W is placed on a horizontal surface. Therefore, the Z direction is the up-down direction.

A silicon germanium (SiGe) film 11 is formed on the wafer W to extend in the X direction. Multiple SiGe films 11 are provided at intervals in the Z direction, and each SiGe film 11 extends in the X direction. When viewed in the X direction, each SiGe film 11, except for the lowermost one, is surrounded by a silicon oxide (SiOₓ) film 12, as illustrated. Similarly to the other SiGe films 11, the lowermost SiGe film 11 is also covered with the SiOₓ film 12. Since, however, the lowermost SiGe film 11 protrudes upward from the surface of the wafer W, no SiOₓ film 12 is formed below the SiGe film 11. Among the SiGe films 11 formed in multiple stages as described above, the SiGe films 11 of some stages form the nanowires or nanosheets described above.

For convenience of description, the multiple SiGe films 11 covered with the SiOₓ film 12 and aligned in the Z direction are collectively referred to as “semiconductor film array 13.” Although not illustrated, multiple semiconductor film arrays 13 are arranged in the Y direction on the wafer W. A carbon-containing silicon oxide film 14, which is an SiOC film, is formed to cover each semiconductor film array 13. More specifically, when viewed in the X direction, the SiOC film 14 is formed to extend from the left side toward the right side of the semiconductor film array 13 via the upper side thereof. The SiOC film 14 enters gaps between adjacent SiGe films 11 from the left and right sides of the semiconductor film array 13 (more specifically, gaps defined by the SiOₓ films 12 surrounding the SiGe films, 11 as illustrated), and is formed so as to fill the gaps.

The SiOC film 14 contains, e.g., 20 atomic % or more and 40 atomic % or less of carbon. Atomic % can be measured using secondary ion mass spectrometry (SIMS) or X-ray photoelectron spectroscopy (XPS). In the plasma etching of the present embodiment, portions of the SiOC film 14 located on the left, right, and upper sides of the semiconductor film array 13 when viewed in the X direction are removed. Therefore, the etching is performed such that portions of the SiOC film 14 interposed between the SiGe films 11 remain after processing.

In the case of etching an SiOC film formed on a wafer W, a technique in which an etching gas containing HF (hydrogen fluoride) gas and NH₃ (ammonia) gas is converted into plasma and the SiOC film is exposed to the plasma may be used. However, in the case of etching an SiOC film having a relatively high carbon content, such as the SiOC film 14 of the present embodiment, the etching amount per unit time is relatively small. Further, such plasma etching has a relatively low etching selectivity relative to Si-containing films other than the SiOC film. In other words, the Si-containing film is etched to a relatively large extent.

In the present embodiment, a mixed gas of NF₃ (nitrogen trifluoride) that is a fluorine-containing gas, O₂ (oxygen), and H₂ (hydrogen) is supplied as an etching gas into a processing chamber containing the wafer W, together with an inert gas for plasma generation. The processing chamber is maintained in a vacuum atmosphere at a predetermined pressure. Then, the wafer W is exposed to the plasma of the etching gas, thereby etching the SiOC film 14.

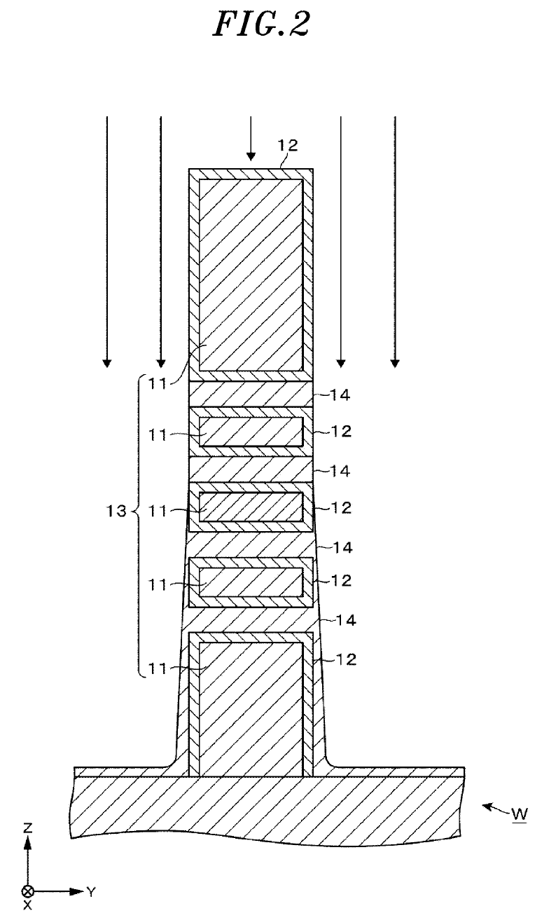

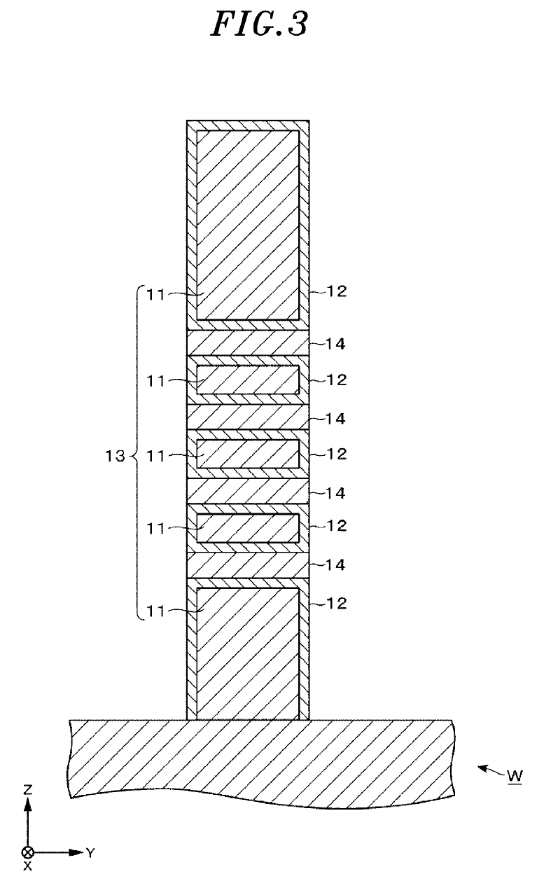

As shown in FIG. 2, during the etching process, a part of the SiOₓ film 12 is covered by the SiOC film 14, whereas another part thereof is exposed. In other words, both the SiOₓ film 12 and the SiOC film 14 are exposed at the surface of the wafer W. The arrows in FIG. 2 indicate plasma. Even when the SiOₓ film 12 is exposed at the surface of the wafer W, the plasma has a high etching selectivity for the SiOC film 14. Thus, the SiOC film 14 is selectively etched, and the etching of the SiOₓ film 12 is suppressed. Then, as shown in FIG. 3, when the portions of the SiOC film 14 that covered the left, right, and upper sides of the semiconductor film array 13 are removed, generation of the plasma is stopped, and the etching process is terminated.

As described above, the SiOC film 14 is etched with high selectivity relative to the SiOₓ film 12. Further, as can be seen from the evaluation tests to be described below, the etching rate (etching amount per unit time) of the SiOC film 14 is relatively high, and the etching process of the SiOC film 14 can be completed in a relatively short time. Although FIG. 2 showing the state during etching illustrates that the upper portion of the SiOC film 14 is removed prior to the lower portion thereof, the present disclosure is not limited thereto.

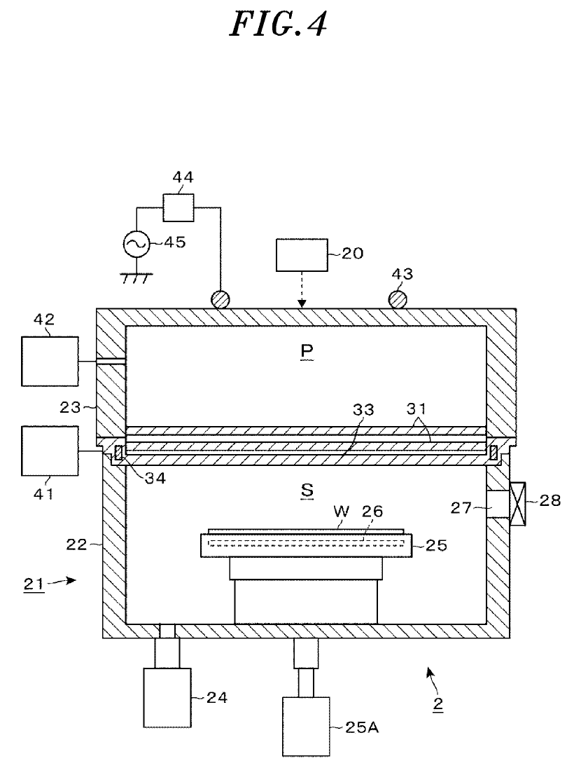

Next, an etching apparatus 2, which is one embodiment of an apparatus for performing the above-described plasma etching process, will be described with reference to the longitudinal cross-sectional side view of FIG. 4. The etching apparatus 2 includes a processing chamber 21 for accommodating a wafer W. The processing chamber 21 includes a chamber body 22 and a lid 23. The chamber body 22 forms the bottom wall and the lower sidewall of the processing chamber 21, and the lid 23 forms the top wall and the upper sidewall of the processing chamber 21. A horizontal partition plate 31 is provided in the processing chamber 21 to divide the inner space of the processing chamber 21 into a processing space S surrounded by the chamber body 22 and a plasma generation space P surrounded by the lid 23. A heat shield plate 33 is horizontally provided below the partition plate 31 to divide the inner space of the processing chamber 21 into upper and lower sections, similarly to the partition plate 31.

An exhaust mechanism 24 including a vacuum pump is connected to the bottom portion of the chamber body 22 to evacuate the processing chamber 21 to a vacuum atmosphere of a desired pressure. Further, a stage 25 is provided in the processing space S, and the wafer W is processed while being horizontally placed on the upper surface of the stage 25. The upper surface of the stage 25 faces the heat shield plate 33. Two stages 25 are provided such that two wafers W can be processed simultaneously. Since, however, the two stages 25 are aligned in the front-back direction in FIG. 4, only one stage 25 is shown in FIG. 4. A temperature control mechanism 26 for controlling the temperature of the wafer W placed on the stage 25 is embedded in the stage 25. The temperature control mechanism 26 includes a channel through which fluid whose temperature is adjusted by a chiller flows, a heater, and the like. In FIG. 4, a reference numeral 27 denotes a transfer port for the wafer W, which is opened at the sidewall of the chamber body 22 such that a transfer mechanism (not shown) can transfer the wafer W to the stage 25, and is opened and closed by a gate valve 28. In FIG. 4, a reference numeral 25A denotes an elevation mechanism that raises and lowers the stage 25 for such transfer.

A first gas supply part 41 and a second gas supply part 42 are provided outside the processing chamber 21. The first gas supply part 41 includes storages that store NF₃ gas, O₂ gas, H₂ gas, and a rare gas so that these gases can be supplied to the plasma generation space P, and a flow rate control mechanism for controlling the flow rates of the gases supplied from the storages to the plasma generation space P. The flow rate control mechanism includes, e.g., a valve or a mass flow controller. The rare gas, which is an inert gas, is, e.g., Ar (argon) gas, and serves to produce plasma and control the pressure in the processing chamber 21.

Similarly to the first gas supply part 41, the second gas supply part 42 includes a gas storage and a flow rate control mechanism so that an inert gas, such as N₂ (nitrogen) gas, can be supplied to the processing space S via the heat shield plate 33 to be described below. N₂ gas is used as a gas for controlling the pressure in the processing chamber 21 and a dilution gas for the etching gas.

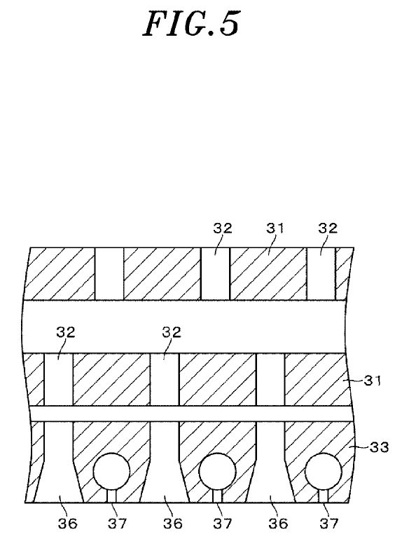

The partition plate 31 and the heat shield plate 33 will be described with reference to the longitudinal cross-sectional side view of FIG. 5. Two partition plates 31 are arranged vertically with a gap interposed therebetween. Each of the two partition plates 31 has a plurality of through-holes 32. The through-holes 32 of the upper partition plate 31 and the through-holes 22 of the lower partition plate 31 are located at different positions in plan view. The misalignment of the through-holes 32 allows the two partition plates 31 to function as so-called ion traps that prevent ions in the plasma generated in the plasma generation space P from being supplied to the processing space S. Therefore, among ions and radicals that are active species of the plasma, radicals are selectively supplied to the processing space S to perform etching.

The heat shield plate 33 serves to prevent heat accumulated in the partition plate 31 due to repeated plasma generation in the plasma generation space P from affecting the distribution of radicals in the processing space S. The peripheral portion of the heat shield plate 33 forms a flange embedded in the sidewall of the chamber body 22. The heat shield plate 33 is cooled by a cooling mechanism 34 embedded in the flange. The cooling mechanism 34 includes, e.g., a channel through which fluid of which temperature is controlled by a chiller flows, or a Peltier element.

The heat shield plate 33 has a plurality of through-holes 36 to allow radicals to be introduced from the plasma generation space P to the processing space S. In plan view, the through-hole 36 overlap the through-holes 32 of the lower partition plate 31. In addition, a plurality of gas outlets 37 are opened on the bottom surface of the heat shield plate 33. Further, the gas supplied from the second gas supply part 42 is supplied from the gas outlets 37 to the processing space S in a shower-like manner through a channel formed in the heat shield plate 33. Therefore, the heat shield plate 33 is configured as a shower head. The through-holes 36 of the heat shield plate 33 and the through-holes 32 of the partition plate 31 are not illustrated in FIG. 4 for simplicity of illustration.

Referring back to FIG. 4, the lid 23 of the processing chamber 21 is made of, e.g., quartz, and serves as a dielectric window. A ring-shaped high-frequency antenna 43 is formed above the lid 23, and the RF antenna 43 is connected to a high-frequency power supply 45 via a matching device 44. The high-frequency power supply 45 outputs a high-frequency power at a predetermined frequency (e.g., 13.56 MHz or higher), thereby generating inductively coupled plasma from the gases supplied to the plasma generation space P. The high-frequency antenna 43, the matching device 44, and the high-frequency power supply 45 constitute a plasma generation mechanism.

The etching apparatus 2 includes a controller 20 that is a computer. The controller 20 includes a program, a memory, and a central processing unit (CPU). The program includes commands (respective steps) for performing the processing of the wafer W and the transfer of the wafer W described above. The program is stored in a storage medium, such as a compact disc, a hard disk, a magneto-optical disc, or a DVD, and installed in the controller 20. The controller 20 outputs control signals to individual components of the etching apparatus 2 based on the program, thereby controlling the operations of the individual components. The operations thus controlled include, e.g., adjustment of the temperature of the stage 25 (i.e., the processing temperature of the wafer W), adjustment of the flow rates of the gases supplied from the first gas supply part 41 and the second gas supply part 42 into the processing chamber 21, adjustment of the exhaust amount by the exhaust mechanism 24 (i.e., adjustment of the pressure in the processing chamber 21), and switching start/stop of plasma generation by ON/OFF of the high-frequency power supply 45.

Hereinafter, the processing procedure for the wafer W using the etching apparatus 2 described above will be described. The wafer W shown in FIG. 1 is placed on the stage 25. Then, in a state where the pressure in the processing chamber 21 is set to, e.g., 1.33 Pa to 133 Pa and the temperature of the wafer W is set to, e.g., 0°C to 120°C, gases are supplied at predetermined flow rates into the processing chamber 21 from the first gas supply part 41 and the second gas supply part 42. The example of the flow rate ratios of the gases will be described in the evaluation test to be described below. Then, the high-frequency power supply 45 supplies a power of, e.g., 200 W to 800 W to the RF antenna 43, thereby converting the gases supplied to the plasma generation space P into plasma.

The radicals constituting the plasma are supplied from the plasma generation space P to the processing space S, so that the etching of the SiOC film 14 described with reference to FIGS. 1 to 3 proceeds. Even if the SiOₓ film 12 is exposed during the etching, the etching of the SiOₓ film 12 is suppressed. Further, the etching apparatus 2 suppresses the supply of ions having relatively high energy in the activated species constituting the plasma to the wafer W. Accordingly, the etching the SiOC film 14 proceeds while reliably suppressing the etching of the SiOₓ film 12. Then, as shown in FIG. 3, when the desired portions of the SiOC film 14 are etched, the power supply from the high-frequency power supply 45 and the supply of gases into the processing chamber 21 are stopped, and the processing is terminated.

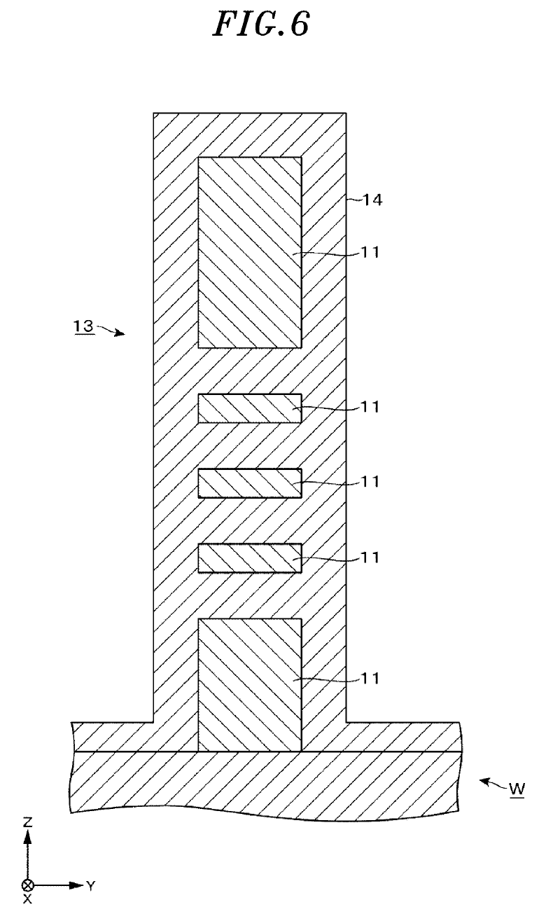

As shown in the evaluation tests to be described below, the plasma etching of the present technology allows the SiOC film to be etched with high selectivity relative to the Si-containing film even when an Si-containing film other than SiGe, such as Si or SiOₓ, and an SiOC film are present at the surface of the wafer W. The wafer W shown in FIG. 6 has a film structure for fabricating a CFET, similarly to that shown in FIG. 1. However, it is different from that shown in FIG. 1 in that the SiOₓ film 12 is not formed on the surface of each SiGe film 11 constituting the semiconductor film array 13, and the SiOC film 14 is in contact with the SiGe films 11.

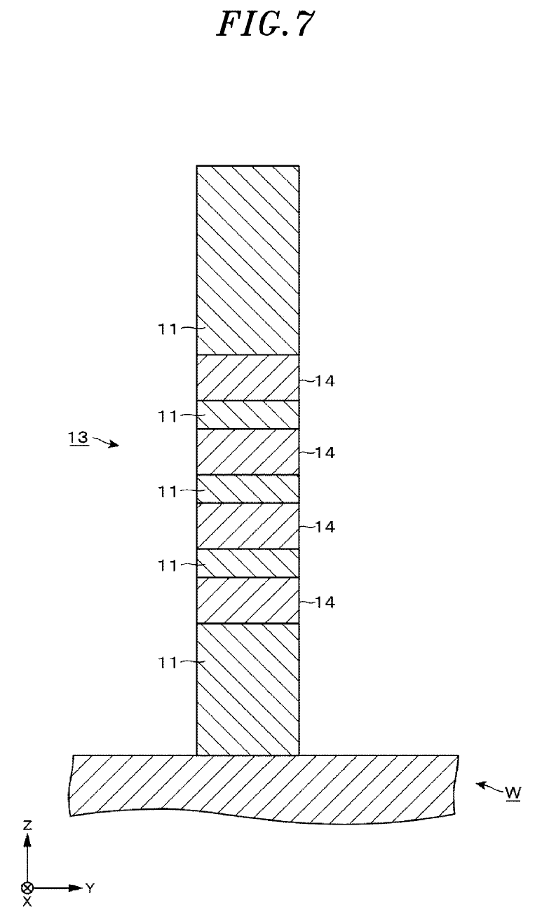

Since the plasma etching of the present technology has the above-described selectivity, even if the SiGe film 11 is exposed during the etching of the SiOC film 14 formed as shown in FIG. 6, the SiOC film 14 surrounding the semiconductor film array 13 can be etched while suppressing the etching of the SiGe film 11. FIG. 7 shows the state in which the etching is terminated.

Although FIGS. 1 and 6 show an example in which the semiconductor film array 13 includes the SiGe films 11, the semiconductor film array 13 may include Si films instead of the SiGe films 11. Therefore, in FIG. 6, the Si films are exposed at the surface during the etching of the SiOC film 14. Even in this case, due to the above-described etching selectivity, the SiOC film 14 can be etched while suppressing the etching of the Si films.

An example in which plasma etching is performed on the SiOC film 14 covering the semiconductor film array 13 has been described as the CFET manufacturing process. In other words, an example in which etching is performed on the SiOC film 14 having irregularities corresponding to the shape of a pattern formed on the surface of the wafer W by covering the pattern has been described. However, as described above, the present technology is not necessarily applied to the CFET manufacturing process, and the SiOC film 14 may be etched in any shape. Therefore, the SiOC film 14 that is formed as a flat film, for example, may be etched using the plasma described above.

Further, in the etching examples described above, one of the Si-containing films, i.e., the Si film, the SiGe film 11, and the SiOₓ film 12, is exposed on the surface during the etching, thereby selectively etching the SiOC film 14 between the Si-containing film and the SiOC film 14. The present disclosure is not limited to the case where both the SiOC film 14 and the Si-containing film are exposed at the surface during the etching. Instead, the films may be exposed at the surface of the wafer W before the etching starts, and the SiOC film 14 may be selectively etched relative to the Si-containing film from the start of the etching. Therefore, for example, a wafer W in which both the SiOC film 14 and the Si-containing film are arranged in the plane direction of the wafer W and exposed at the surface may be loaded into the etching apparatus 2, and the SiOC film 14 may be selectively etched.

The Si-containing film is a film that contains Si and is different from a carbon-containing silicon oxide film that is an etching target. The Si-containing film is a film that does not contain carbon, for example. More specifically, the Si-containing film may be an SiN (silicon nitride) film other than the Si film, the SiGe film, and the SiOₓ film described above. The evaluation tests to be described below demonstrate that the plasma etching described above achieves a high etching selectivity for the carbon-containing silicon oxide film relative to the SiN film. It is considered that the etching of each Si-containing film is suppressed because the active species of plasma generated from O₂ gas and H₂ gas constituting the etching gas are adhered to the surface of the Si-containing film and serve as a protective film against the plasma.

Further, in the case of etching the SiOC film 14 using the plasma described above, both the SiOC film 14 and the Si-containing film are not necessarily exposed over the surface. In other words, the etching may be performed such that only the SiOC film 14 is exposed on the substrate surface from the start to the end of the processing. Even in this case, the present technology achieves the effect of etching the SiOC film 14 at a relatively high etching rate.

The Si-containing film will be described further. Here, the description stating that a film contains Si does not mean that Si is inevitably contained as an impurity, but means that Si is contained as a constituent component. Further, in this specification, the description stating that a film other than the Si-containing film or an etching gas contains a specific component means that the film or the etching gas contains the component as a constituent component, not as an impurity, similarly to Si in the Si-containing film. Although the case where the Si-containing film is a film that does not contain carbon has been described as an example, the description stating that carbon is not contained means that carbon is not contained as a constituent component, and does not mean that carbon that is inevitably mixed in as an impurity is not contained.

The carbon-containing silicon oxide film to be etched is not limited to the SiOC film 14. Specifically, the etching target may be, e.g., an SiCOH film containing hydrogen in addition to Si, O, and C, or an SiOCN film containing nitrogen in addition to Si, O, and C. The atomic % of carbon contained in the SiCOH film and the SiOCN film is the same as the atomic % of carbon contained in the SiOC film 14 described above.

The fluorine-containing gas constituting the etching gas is not limited to NF₃ gas, and other fluorine-containing gases, such as F₂ (fluorine) gas and the like, may be used. Although an example using oxygen as an oxygen-containing gas constituting the etching gas has been described, O₃ (ozone) gas, CO (carbon monoxide) gas, CO₂ (carbon dioxide) gas, or the like may also be used to supply oxygen radicals to the wafer W. Therefore, it is considered that the effects similar to those obtained in the case of using oxygen gas can be achieved.

Although the etching apparatus 2 described above is configured to generate inductively coupled plasma, the plasma generation method may be arbitrary. Accordingly, it is possible to use, e.g., an apparatus in which a shower head and a stage installed in a processing chamber are configured as parallel plate electrodes facing each other, and capacitively coupled plasma is generated from a gas supplied from the shower head toward the stage, thereby etching the wafer W on the stage. Further, so-called remote plasma processing in which plasma generated at a location distant from the processing chamber is supplied into the processing chamber to perform processing may be performed. However, an apparatus configuration in which inductively coupled plasma is generated in the processing chamber is advantageous in that the etching of the Si-containing film by the action of ions can be suppressed by providing the partition plate 31 serving as an ion trap as described with reference to FIGS. 4 and 5.

It should be noted that the above-described embodiments are illustrative in all respects and are not restrictive. The above-described embodiments may be omitted, replaced, changed, or combined in various forms without departing from the scope of the appended claims and the gist thereof.

### [Evaluation tests]

Evaluation tests that have conducted in relation to the present technology will be described. A wafer W with five chips mounted on the surface thereof was prepared. A film was formed on the top surface of each chip, and different types of films were formed on different chips. Specifically, an SiOC film, an SiN film, an SiOₓ film, a polysilicon film, and an SiGe film were formed, and one of them was formed on one chip. In the evaluation tests, carbon was contained in the SiOC film at 30 atomic % or more and 40 atomic % or less.

As the evaluation test, the wafer W was loaded into the etching apparatus 2 described in the embodiment and subjected to plasma etching for a predetermined period of time. After the etching process, the etching amount of the film formed on each chip was measured. Further, the etching selectivity was calculated for films other than the SiOC film based on the etching amount of the SiOC film. The etching selectivity is calculated by dividing the etching amount of the SiOC film by the etching amount of a film for which etching selectivity is to be determined. Therefore, a higher etching selectivity indicates that the etching amount of the film is suppressed, and the etching selectivity relative to the SiOC film is high.

In the etching process in the evaluation tests, the pressure in the processing chamber 21 and the power supplied from the high-frequency power supply 45 were set within the ranges described in the embodiment. Further, the flow rate ratio of the gases supplied into the processing chamber 21 was set to NF₃ gas: H₂gas: O₂ gas: N₂ gas: Ar gas = 1:1:1:14:1.

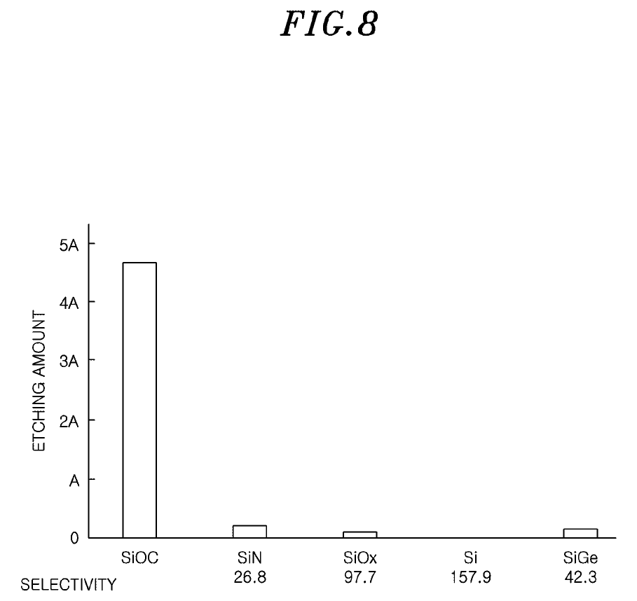

FIG. 8 is a graph showing the results of the evaluation test. In the graph, the vertical axis represents the etching amount, and is graduated at predetermined increments A. Further, the etching selectivities for the SiN film, the SiOₓ film, the polysilicon film, and the SiGe film were 26.8, 97.7, 157.9, and 42.3, respectively. As described above, the etching selectivities were relatively high for each of the SiN film, the SiOₓ film, the polysilicon film, and the SiGe film. Therefore, as described in the embodiments, it was confirmed that, in the case of etching the SiOC film using the present technology, it was possible to suppress the etching amount of the Si-containing films other than the SiOC film, and also possible to obtain a high etching rate for the SiOC film. In particular, since the etching selectivities for the SiOₓ film, the polysilicon film, and the SiGe film are high, the present technology is effective for etching the SiOC film relative to these films. Accordingly, as described in the embodiments, it was demonstrated that it is effective to apply the present technology to the CFET manufacturing process in which these films are exposed during the etching of the SiOC film.

Since an extremely high etching selectivity with respect to each Si-containing film can be obtained, it is expected that a practically sufficient selectivity can be obtained even when an SiOC film contains less than 30 atomic % of carbon atoms. Specifically, as described in the embodiments, it is expected that a sufficient etching selectivity can be obtained as long as an SiOC film contains 20 atomic % or more of carbon atoms.

In the evaluation test, the flow rate ratio of NF₃ gas, O₂ gas, and H₂ gas constituting the etching gas was 1:1:1. Since, however, an extremely high etching selectivity was obtained for each Si-containing film as described above, it is expected that practically sufficient effects can be obtained even if there is slight variation in the flow rate ratio. On the assumption that the flow rate of NF₃ gas is 1, it is expected that the etching can be performed with a sufficient selectivity even if the gases are supplied to the wafer W at a ratio where the flow rate of O₂ gas is 0.2 to 10 and the flow rate of H₂ gas is 0.2 to 10. Further, on the assumption that the flow rate of NF₃ gas is 1, if the flow rates of O₂ gas and H₂ gas are set to 0.5 to 1.5, which are closer to the conditions set in the test, the etching with a reliably high selectivity can be performed. Although detailed results are omitted, when the etching gas containing only NF₃ gas and O₂ gas without containing H₂gas was supplied, the high etching selectivity for the SiOC film as observed in the evaluation tests was not obtained. Therefore, in order to increase the etching selectivity of the SiOC film, it is effective that H₂gas is included in the etching gas.

1. An etching method for etching a carbon-containing silicon oxide film formed on a substrate by exposing the carbon-containing silicon oxide film to plasma generated from an etching gas containing a fluorine-containing gas, an oxygen-containing gas, and a hydrogen gas.

2. The etching method of claim 1, wherein the oxygen-containing gas is oxygen.

3. The etching method of claim 2, wherein the fluorine-containing gas is nitrogen trifluoride.

4. The etching method of claim 3, wherein the carbon-containing silicon oxide film is an SiOC film.

5. The etching method of claim 1, wherein a carbon content in the carbon-containing silicon oxide film is 20 atomic % or more and 40 atomic % or less.

6. The etching method of claim 1, wherein the carbon-containing silicon oxide film and a silicon-containing film are formed on the substrate,
the method further comprising:
exposing the carbon-containing silicon oxide film and the silicon-containing film to the plasma to selectively etch the carbon-containing silicon oxide film between the carbon-containing silicon oxide film and the silicon-containing film.

7. The etching method of claim 6, wherein the silicon-containing film is a silicon film, a silicon oxide film, or a silicon germanium film.

8. An etching apparatus comprising:
a processing chamber that accommodates a substrate on which a carbon-containing silicon oxide film is formed;
a gas supply part configured to supply, into the processing chamber, an etching gas containing a fluorine-containing gas, an oxygen-containing gas, and a hydrogen gas; and
a plasma generation mechanism configured to generate plasma for etching the carbon-containing silicon oxide film by exposing the carbon-containing silicon oxide film to the plasma of the etching gas.
